(19) United States
(12) Patent Application Publication
(10) Pub. No.: US 2007/0015065 A1
(43) Pub. Date: Jan. 18, 2007

(54) EUV EXPOSURE MASK BLANKS AND THEIR FABRICATION PROCESS, AND EUV EXPOSURE MASK

(75) Inventors: Tsukasa ABE, Tokyo (JP); Shiho SASAKI, Tokyo (JP)

Correspondence Address: PATENTTM.US, P. O. BOX 82788, PORTLAND, OR, 97282-0788, US

(73) Assignee: DAI NIPPON PRINTING CO., LTD., Tokyo (JP)

(21) Appl. No.: 11/383,856

(22) Filed: May 17, 2006

(30) Foreign Application Priority Data
May 17, 2005 (JP) 2005-143352

(51) Int. Cl. G03F 1/00

(52) U.S. Cl. 430/5

(57) ABSTRACT

The invention provides a mask blank for EUV exposure wherein a substrate is provided at its flank with an electrically conductive film unlikely to peel off in EUV exposure mask fabrication process steps, etc. and its fabrication process, and provide a mask for EUV exposure which is readily attachable to or detachable from an electrostatic chuck, thereby foreclosing the possibility of the mask remaining clinging firmly to the electrostatic chuck after EUV exposure and being hard to detach from it. A mask blank for EUV exposure is provided, in which on one major surface of a substrate, a reflective layer adapted to reflect EUV light and an absorptive layer located on said reflective layer for absorption of said EUV light are at least provided as a pattern-formation layer. An electrically conductive layer is formed on another major surface of the substrate, and the pattern-formation layer and the conductive layer on the opposite major surfaces of the substrate are in conduction with each other via one or more flank conductive films provided at the flank of the substrate.

### BACKGROUND OF THE INVENTION

The present invention relates generally to a mask blank for lithography in the fabrication of semiconductor devices, etc. and its fabrication process as well as a mask for lithography, and more particularly to a mask blank for EUV exposure (EUV is an acronym of extreme ultraviolet) for the fabrication of the mask to transfer a mask pattern onto a wafer using EUV and its fabrication process as well as a mask for EUV exposure.

As semiconductor devices are now much finer, there is an exposure technique available, in which patterns are transferred onto wafers under photomasks, employing optical projection aligners using KrF or ArF excimer lasers. Before long, however, exposure techniques relying on such optical projection aligners would reach their own resolution limits; so there are new transfer techniques proposed such as direct lithography by electron beam lithography systems, electron beam projection lithography: EPL), low energy electron beam projection lithography: LEEPL), and EUV lithography.

Among new such lithography techniques, EUV exposure now attracts much attention as a lithography technique capable of being applied to semiconductor devices over two or more generations. This is because EUV exposure makes use of extreme ultraviolet light (EUV light having a wavelength of 13.5 nm) much shorter in wavelength than excimer lasers so that exposure can be implemented on a size usually reduced down to about ¼; it is thought of as limits of making the wavelength of ultraviolet exposure shortest.

For EUV exposure, because of being unable to use a dioptric system due to short wavelengths, it is proposed to use a catoptric system and employ a reflection type mask as the mask (for instance, see patent publications 1 and 2).

FIG. 9 is illustrative of one example of such a prior art EUV exposure mask blank and EUV exposure mask. An EUV exposure mask blank depicted in FIG. 9(a) have a structure such that a reflective layer 92 having a multilayer structure and adapted to reflect EUV light is located on a substrate 91, an etching stopper layer 93 is provided on the reflective layer 92, and an absorptive layer 94 for absorption of EUV light is formed on that etching stopper layer. An EUV exposure mask depicted in FIG. 9(b), on the other hand, is formed by patterning the absorptive layer of the above mask blank, and removing off the etching stopper layer 93 on the basis of the patterned absorptive layer. Upon incidence on the EUV exposure mask, the EUV light is reflected at the reflective layer 92 while absorbed in the absorptive layer 94, so that the reflected EUV light produces a reduced transfer pattern on a wafer.

With a mask attached to an aligner for implementing EUV exposure, as the mask sags even a bit due to its own weight, it brings on a misalignment in the post-transfer pattern. To prevent this, an electrostatic chuck is used to hold the mask in place. To this end, an electrically conductive layer must be provided facing away from the surface with an EUV exposure mask pattern formed on it to keep the mask in place.

However, the EUV exposure mask having an electrically conductive layer is often likely to remain clinging firmly to the electrostatic chuck after EUV exposure, rendering its removal hard; there are problems arising in connection with the time taken for detachment operation, and contamination of the surface of the mask.

There is one possible approach to obviating such problems, wherein, to bring both major surfaces of an EUV exposure mask blank in conduction with each other thereby facilitating removal of charges on the back surface, an electrically conductive layer is formed all around the flank of a blank substrate at the time of mask blank fabrication, for instance, the formation of films on both major surfaces of the blank substrate by sputtering.
Patent Publication 1: JP-B7-27198
Patent Publication 2: JP-A8-213303

During mask fabrication using a mask blank with an electrically conductive film formed all around the flank of the substrate, however, the flank of the mask comes in contact with a pin of a mask holder chuck at a mask fabrication process step such as a washing or drying step or when the mask is washed to clear out it from stains resulting from exposure. This in turn causes the conductive film at the flank of the substrate to be mechanically rubbed due to the high speed rotation of the chuck, etc., ending up with a peel of the conductive film at the flank of the substrate and, hence, leading to contamination of the system or re-deposition of the once peeled film onto the mask, which are otherwise responsible for mask defects or other problem.

### SUMMARY OF THE INVENTION

In view of such problems as mentioned above, an object of the present invention is to provide a mask blank for EUV exposure wherein a substrate is provided at its flank with an electrically conductive film unlikely to peel off in EUV exposure mask fabrication process steps, etc. and its fabrication process, and provide a mask for EUV exposure which is readily attachable to or detachable from an electrostatic chuck, thereby foreclosing the possibility of the mask remaining clinging firmly to the electrostatic chuck after EUV exposure and being hard to detach from it.

The invention of claim 1 is directed to a mask blank for EUV exposure in which on one major surface of a substrate, a reflective layer adapted to reflect EUV light and an absorptive layer located on said reflective layer for absorption of said EUV light are at least provided as a pattern-formation layer, characterized in that an electrically conductive layer is formed on another major surface of said substrate, and said pattern-formation layer and said conductive layer on the opposite major surfaces of said substrate are in conduction with each other via one or more flank conductive films provided at a flank of said substrate.

In the invention of claim 2, the mask blank for EUV exposure according to claim 1 is further characterized in that said flank conductive film is composed of the same material as that of said conductive layer.

In the invention of claim 3, the mask blank for EUV exposure according to claim 1 is further characterized in that said flank conductive film is composed of the same material as that of said pattern-formation layer.

In the invention of claim 4, the mask blank for EUV exposure according to claim 1 is further characterized in that said flank conductive film is composed of a material contained in said conductive layer and said pattern-formation layer.

The invention of claim 5 is directed to a mask for EUV exposure, characterized in that it is fabricated using the mask blank for EUV exposure according to any one of claims 1-4.

The invention of claim 6 is directed to a process for fabrication of a mask blank for EUV exposure in which on one major surface of a substrate, a reflective layer adapted to reflect EUV light and an absorptive layer located on said reflective layer for absorption of said EUV light are at least provided as a pattern-formation layer, characterized by involving steps of (1) forming said reflective layer on one major surface of said substrate, (2) forming said absorptive layer on said reflective layer, (3) forming an electrically conductive layer on another major surface of said substrate, and (4) forming one or more flank conductive films at a flank portion of said substrate.

In the invention of claim 7, the process for fabrication of a mask blank for EUV exposure according to claim 6 is further characterized in that said conductive layer and said flank conductive film are simultaneously formed.

In the invention of claim 8, the process for fabrication of a mask blank for EUV exposure according to claim 6 is further characterized in that said pattern-formation layer and said flank conductive film are simultaneously formed.

In the invention of claim 9, the process for fabrication of a mask blank for EUV exposure according to claim 6 is further characterized in that said flank conductive film is formed by formation of said conductive layer and formation of said pattern-formation layer.

In the invention of claim 10, the process for fabrication of a mask blank for EUV exposure according to claim 6 is further characterized in that said flank conductive film is formed separately from formation of said conductive layer or formation of said pattern-formation layer.

In the invention of claim 11, the process for fabrication of a mask blank for EUV exposure according to any one of claims 6-10 is further characterized in that said flank conductive film is formed by a vacuum film-formation technique using a mask holder having a cutout space at a site with said flank conductive film formed thereon.

According to the EUV exposure mask blank of the invention, the formation of an electrically conductive film at the flank of the mask blank at a site in mechanical contact with a mask jig is beforehand avoided, so that there is no peel of the flank conductive film, which prevents contamination of a mask and a mask fabrication system, resulting in much fewer mask defects count.

According to the inventive process for the fabrication of a mask blank for EUV exposure, an electrically conductive film is formed at any desired position of the flank of the substrate at the time of forming a mask blank-formation thin film, so that the mask blank can be easily fabricated.

The EUV exposure mask of the invention has another advantage that, since it is capable of ready attachment to, or ready detachment from, an electrostatic chuck, there is no contamination of a mask or a mask fabrication system due to a peel of the flank conductive film, ensuring much fewer mask defects count.

Still other objects and advantages of the invention will in part be obvious and will in part be apparent from the specification.

The invention accordingly comprises the features of construction, combinations of elements, and arrangement of parts which will be exemplified in the construction hereinafter set forth, and the scope of the invention will be indicated in the claims.

### BRIEF ESCRIPTION OF THE DRAWINGS

FIG. 1 is schematically illustrative in section of one exemplary mask blank for EUV exposure according to the invention.

FIG. 2 is illustrative in schematic of one embodiment of the mask blank for EUV exposure according to the invention.

FIG. 3 is illustrative in schematic of another embodiment of the mask blank for EUV exposure according to the invention.

FIG. 4 is illustrative in schematic of yet another embodiment of the mask blank for EUV exposure according to the invention.

FIG. 5 is illustrative in schematic of the steps of one fabrication process for the inventive mask blank for EUV exposure, shown in FIG. 2.

FIG. 6 is schematically illustrative in section of the steps of another fabrication process for the inventive mask blank for EUV exposure.

FIG. 7 is schematically illustrative in section of the steps of yet another fabrication process for the inventive mask blank for EUV exposure.

FIG. 8 is schematically illustrative in section of one exemplary structure of the inventive mask for EUV exposure.

FIG. 9 is illustrative in schematic of sectional structures of a prior art mask blank and mask for EUV exposure.

### DESCRIPTION OF THE PREFERRED EMBODIMENTS

Some embodiments of the inventive mask blank for EUV exposure and its fabrication process as well as of the inventive mask for EUV exposure are now explained with reference to the accompanying drawings.

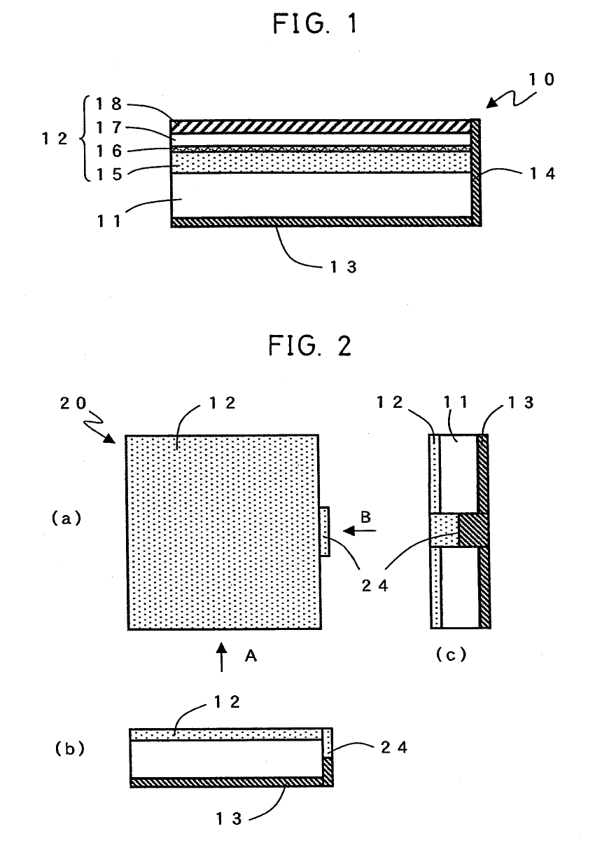

FIG. 1 is schematically illustrative in section of one example of the inventive mask blank for EUV exposure, and FIGS. 2, 3 and 4 are illustrative in schematic of embodiments of the inventive mask blank for EUV exposure. In FIGS. 2, 3 and 4, the same references as in FIG. 1 are indicative of the same sites and materials.

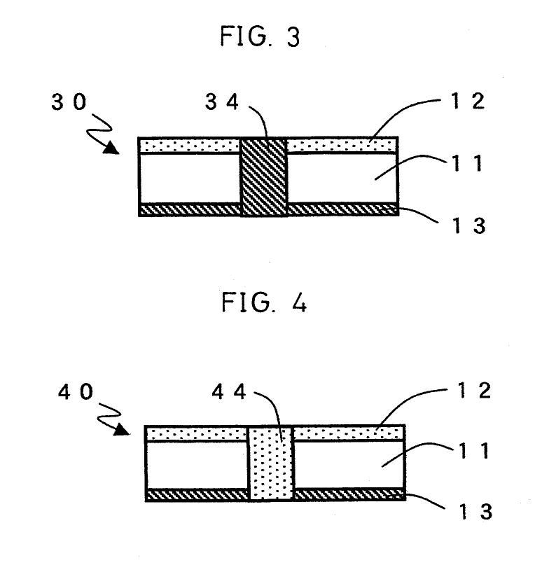

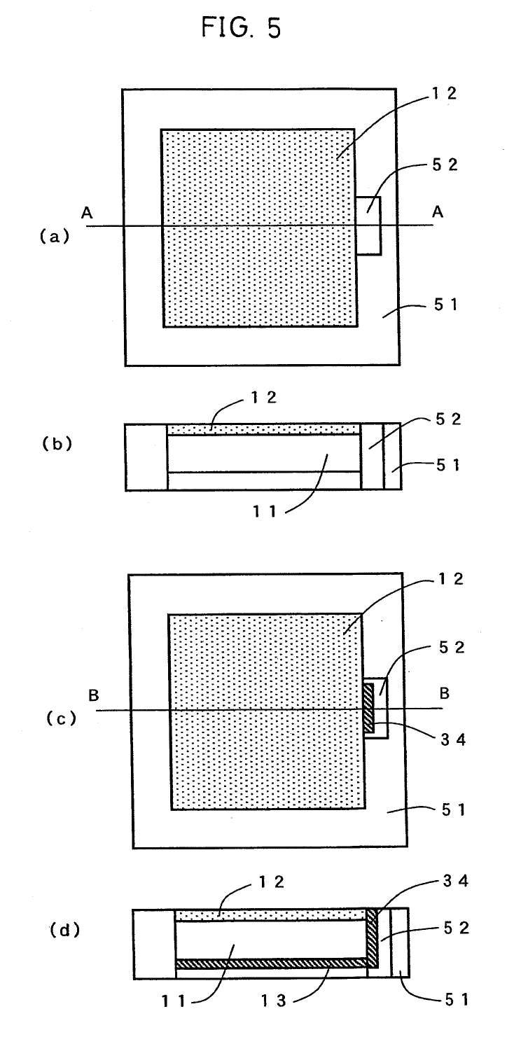

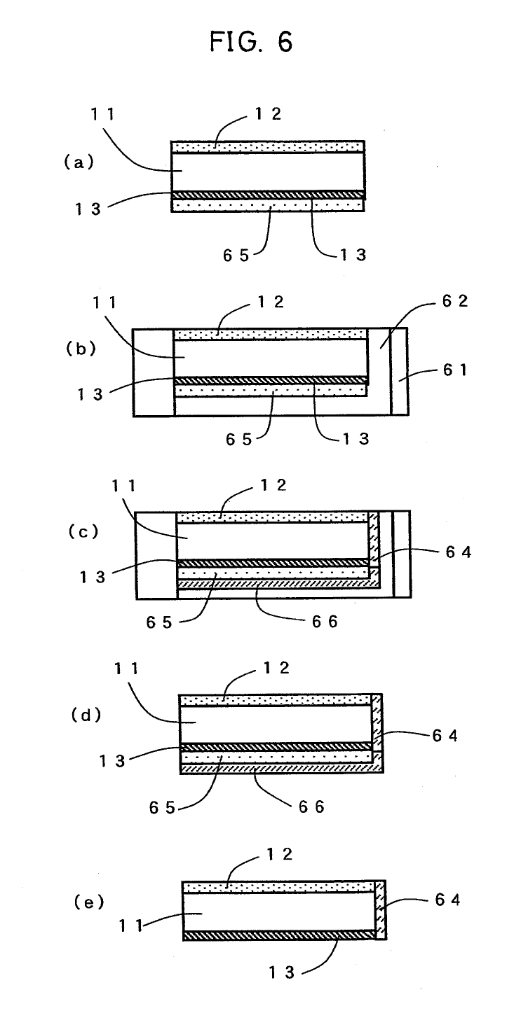

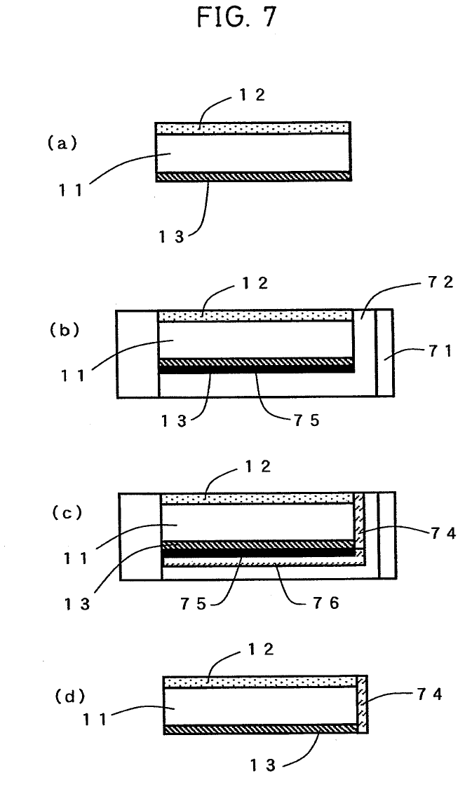

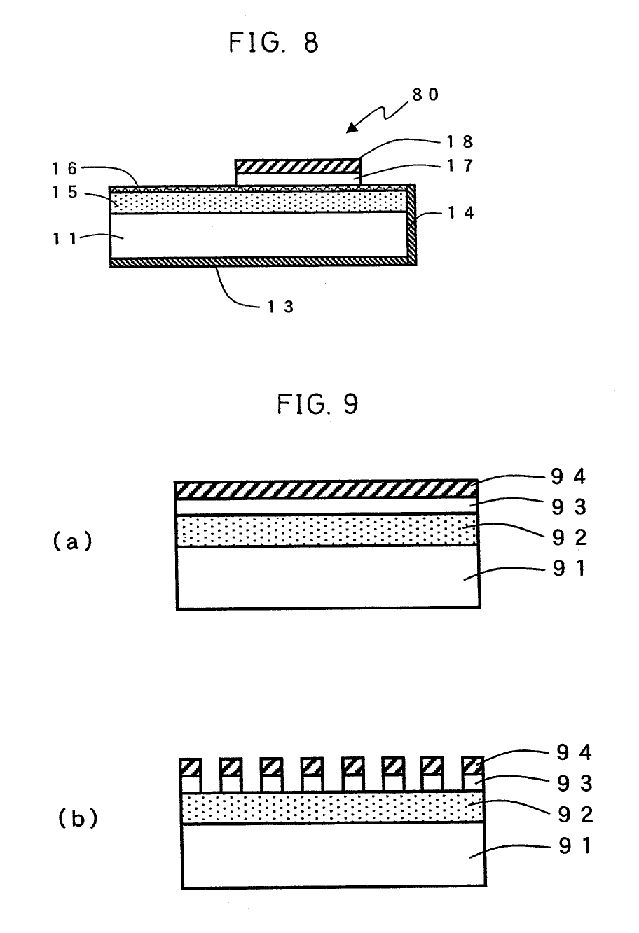

FIG. 5 is illustrative in schematic of the steps of the fabrication process for the inventive mask blank for EUV exposure, depicted in FIG. 3. FIGS. 6 and 7 are schematically illustrative in section of the steps of other fabrication processes for the inventive mask blank for EUV exposure. FIG. 8 is schematically illustrative in section of one exemplary structure of the inventive mask for EUV exposure.

### Mask Blank for EUV Exposure

As depicted in FIG. 1, the inventive mask blank 10 for EUV exposure comprises a pattern-formation layer 12 formed on one major surface of a substrate 11 and an electrically conductive layer 13 formed on another major surface of the substrate 11, wherein the pattern-formation layer 12 and the conductive layer 13 on the opposite major surfaces of the substrate 11 are in conduction with each other via at least one flank conductive film 14 located at the flank of the substrate 11.

The pattern-formation layer 12 at least comprises a reflective layer 15 that reflects EUV light and an absorptive layer 18 located on that reflective layer for absorption of EUV light; however, the absorptive layer 18 is not necessarily in direct contact with the reflective layer 15. Usually, the pattern-formation layer 12 is provided with an etching stopper layer 17 (also called a buffer layer) between the reflective layer 15 and the absorptive layer 18 for the purpose of preventing damages to the underlying reflective layer 15 at the time of dry etching the absorptive layer 18 in a pattern form.

Optionally or if required, the pattern-formation layer 12 may be provided with a capping layer 16 on the reflective layer 15 for the purpose of prevention of oxidation of the reflective layer, or the like. Sometimes, to enhance the reflection contrast of inspection light (250 nm) at the time of mask inspection, a low-reflection layer such as TaO may be provided on the absorptive layer 18 (not shown).

Each component of the mask blank for EUV exposure is now explained.

### Substrate

For the substrate 11 of the inventive mask blank 10 for EUV exposure, it is preferable to use a material that has a low coefficient of thermal expansion so as to keep pattern alignment accuracy high, possesses high smoothness and flatness so as to obtain high reflectivity and high transfer accuracy, and has high resistance to a washing fluid used for washing, etc. in a mask fabrication process. For instance, low thermal expansion glasses such as quartz glass and SiO₂—TiO₂ glass, glass substrates such as crystallized glass resulting from precipitation of β-quartz solid solutions, and metal substrates such as silicon and Fe-Ni inver alloys may be used. The flatness of the mask blank, for instance, must be 50 nm or lower in a pattern area.

### Pattern-Formation Layer

For the reflective layer 15 that forms a part of the pattern-formation layer 12, a material capable of reflecting EUV light used for EUV exposure with high reflectivity is used. To this end a multilayer film comprising molybdenum and silicon is frequently used. For instance, a reflective layer formed of a multilayer comprising 40 Mo layers, each being 2.74 nm thick, and 40 Si layers, each being 4.11 nm thick, is used. Besides, Ru/Si, Mo/Be, Mo compound/Si compound, Si/Nb periodic multilayer film, Si/Mo/Ru periodic multilayer film, Si/Mo/Ru/Mo periodic multilayer film, Si/Ru/Mo/Ru periodic multilayer film, etc., too, may be used as the material having high reflectivity in a specific wavelength range. However, the optimum film thickness varies from material to material.

The multilayer film comprising Mo and Si may be prepared by a DC magnetron sputtering technique wherein a silicon target is first used to form a silicon film in an argon gas atmosphere, and a molybdenum target is then used to form a molybdenum film in an argon gas atmosphere, thereby forming one period of film. Then, 30 to 60, preferably 40, such periods of films are stacked together. Finally, the formation of a silicon film gives a reflective film comprising a multilayer film.

### Capping Layer

As the layer that forms a part of the pattern-formation layer 12, the capping layer 16 may optionally be provided on the reflective layer 15 by formation of a silicon or ruthenium film by sputtering or the like for the purposes of preventing oxidation of the reflective layer and protecting the reflective layer against mask washing.

### Etching Stopper Layer

As the layer that forms a part of the pattern-formation layer 12, usually, the etching stopper layer (also called the buffer layer) 17 is provided between the reflective layer 15 and the absorptive layer 18 so as to prevent damages to the underlying layer 15 at the time when the absorptive layer 18 for absorption of EUV light used for EUV exposure is pattern etched as by dry etching.

In most cases, SiO₂ is used as the material for the etching stopper layer 17; however, it is acceptable to make use of Al₂O₃, Cr, CrN, etc. as the material of high etching resistance, although dependent on absorptive layer-etching conditions.

When SiO₂ is used, it is preferable that a SiO₂ film is formed on the reflective layer comprising the above multilayer film by an RF magnetron sputtering technique wherein a SiO₂ target is used in an argon atmosphere.

### Absorptive Layer

For the material for the absorptive layer 18 that forms a part of the pattern-formation layer 12 and is adapted to absorb EUV light, for instance, Ta, TaN, a material comprising Ta as a major component, Cr, and a material that comprises Cr as a major component and at least one component selected from N, O and C may be used. Besides, materials such as TaSi, TaSiN, TaGe, TaGeN, WN, and TiN may also be used.

### Conductive Layer

In the invention, the electrically conductive layer 13 is formed on another major surface of the substrate 11 opposite to the pattern-formation layer 12 formed on one major surface of the substrate 11. As already noted, the conductive layer 13 is for attachment to the electrostatic chuck of a mask for EUV exposure, and is made up of a metal or metal compound thin film that has an electrical conductivity and a thickness of about 80 to 150 nm, for instance, a Cr or CrN thin film.

### Flank Conductive Film

In the mask blank of the present invention, the pattern-formation layer 12 and the conductive layer 13 on the opposite major surfaces of the above substrate are in conduction with each other via at least one flank conductive film 14 located at the flank of the substrate. The flank conductive film 14 may be made up of the same material as that of the conductive layer 13, the same material as that of the pattern-formation layer 12, or both the materials for the conductive layer 13 and the pattern-formation layer 12. Note here that it is not always necessary to use all the layers that form the pattern-formation layer. For instance, the flank conductive film may be formed of the material for the electrically conductive, reflective or absorptive layer. For the material for the flank conductive film 14, for instance, use may be made of a metal or metal compound thin film exhibiting electrical conductivity such as Cr, and CrN, or a multilayer film comprising Mo, Si, and Mo and Si, all having preferably a thickness of about 80 nm to about 150 nm.

The flank conductive film 14 is preferably formed simultaneously with the formation of the pattern-formation layer 12 and/or the conductive layer 13, because the fabrication process can be cut back on the same vacuum system.

Alternatively, only the flank conductive film 14 may be formed in any separate step.

The flank conductive film 14 is located at a position with a width such that in the mask blank fabrication step, the mask fabrication step and the EUV exposure step, the flank is not in mechanical contact with the jig, etc. How many flank conductive films 14 are located may be optionally determined.

In the way as described above, the inventive mask blank for EUV exposure such as one shown in FIG. 1 is obtained.

Several embodiments of the flank conductive film 14 are now explained.

### First Embodiment

FIG. 2(a) is a top view of the mask blank 20 for EUV exposure that is one example of the present invention; FIG. 2(b) is a side view as taken from an arrow A direction; and FIG. 2(c) is a side view as taken from an arrow B direction.

As depicted in FIG. 2, in the inventive mask blank 20 for EUV exposure, a reflective layer that reflects EUV light and an absorptive layer located on that reflective layer for absorption of EUV light are at least provided as the pattern-formation layer 12 on one major surface of the substrate 11, and the electrically conductive layer 13 is formed on another major surface of the substrate 11. And then, the pattern-formation layer 12 and the conductive layer 13 on the opposite major surfaces of the substrate 11 are in conduction with each other via at least one flank conductive film 24 provided at the flank of the substrate 11. The conductive film 24 depicted in FIG. 2 are made up of materials contained in both the pattern-formation layer 12 and the conductive layer 13, and near the middle of the flank conductive film 24 the materials contained in both overlap.

The flank conductive film 24 may be formed simultaneously with the formation of the pattern-formation layer 12 and the conductive layer 13 as by sputtering.

### Second Embodiment

In the inventive mask blank 30 for EUV exposure depicted in FIG. 3, a reflective layer that reflects EUV light and an absorptive layer located on that reflective layer for absorption of EUV light are at least provided as the pattern-formation layer 12 on one major surface of the substrate 11, and the electrically conductive layer 13 is formed on another major surface of the substrate 11. And then, the pattern-formation layer 12 and the conductive layer 13 on the opposite major surfaces of the substrate 11 are in conduction with each other via at least one flank conductive film 34 provided at the flank of the substrate 11. The flank conductive film 34 is made up of the same material as that for the conductive layer 13.

The flank conductive film 34 may be formed simultaneously with the formation of the conductive layer 13 as by sputtering.

### Third Embodiment

In the inventive mask blank 40 for EUV exposure depicted in FIG. 4, a reflective layer that reflects EUV light and an absorptive layer located on that reflective layer for absorption of EUV light are provided as the pattern-formation layer 12 on one major surface of the substrate 11, and the electrically conductive layer 13 is formed on another major surface of the substrate 11. And then, the pattern-formation layer 12 and the conductive layer 13 on the opposite major surfaces of the substrate 11 are in conduction with each other via at least one flank conductive film 44 provided at the flank of the substrate 11. The flank conductive film 44 is made up of the same material as that for the pattern-formation layer 12.

The flank conductive film 44 may be formed simultaneously with the formation of the pattern-formation layer 12 as by sputtering.

### Fabrication Process of the Mask Blank for EUV Exposure

The fabrication process of the inventive mask blank for EUV exposure involves the steps of forming a reflective layer that reflects EUV light on one major surface of a substrate, forming on that reflective layer an absorptive layer for absorption of EUV light, forming an electrically conductive layer on another major surface of the substrate, and forming at least one flank conductive film at the flank of the substrate.

Several embodiments of the fabrication process of the inventive mask blank for EUV exposure are now explained primarily with reference to how to form the flank conductive film.

### First Embodiment

The first embodiment is directed to the EUV exposure mask blank fabrication process wherein a thin-film layer that forms a mask blank is formed by a vacuum film-formation technique using a mask holder having a cutout space at a site where a flank conductive film is to be formed and, at the same time, the flank conductive film is formed.

With the EUV exposure mask blank of FIG. 3 in mind, reference is made to FIG. 5.

The pattern-formation layer 12 is formed on one major surface of the substrate 11 at a given thickness as by sputtering, and then placed in a mask holder 51 having a cutout space 52, as depicted in FIG. 5(a). FIG. 5(b) is a sectional view as taken on A-A line in FIG. 5(a).

Then, as depicted in FIG. 5(c), the electrically conductive layer 13 is formed on another major surface of the substrate 11 at a given thickness as by sputtering. FIG. 5(d) is a sectional view as taken on B-B line in FIG. 5(c). Simultaneously with this, the flank conductive film 34 is formed at the flank of the substrate 11 in the mask holder 51 with the cutout space 52 located, giving the inventive mask blank for EUV exposure.

### Second Embodiment

The second embodiment is directed to a process of fabricating an EUV exposure mask blank having a flank conductive film by a liftoff technique, which process is well fit for where, upon formation of films on both major surfaces of the substrate, the sputtered films do not fully come down to the flank.

As depicted in FIG. 6(a), the pattern-formation layer 12 is provided on one major surface of the substrate 11 at a given thickness as by sputtering, and the electrically conductive layer 13 is formed on another major surface of the substrate 11 at a given thickness as by sputtering.

Then, a liftoff material is coated or laminated on the conductive layer 13 to form a liftoff layer 65 of about 0.1 to 1 μm in thickness. For the liftoff layer 65, for instance, a layer obtained by coating of a photosensitive resin solution or a dry film is used.

Then, as depicted in FIG. 6(b), the above substrate is placed in a mask holder 61 having a cutout space 62.

Then, as depicted in FIG. 6(c), an electrically conductive material is formed as by sputtering on the liftoff layer 65 on another major surface of the substrate 11, and at the flank of the substrate 11 in the holder 61 having a cutout space 62, thereby forming an electrically conductive layer 66 and a flank conductive film 64.

Then, the above substrate is detached from the mask holder (FIG. 6(d)), and the liftoff layer 65 is lifted off with a solvent in which the liftoff layer 65 is dissolvable, thereby allowing the conductive film 66 on the liftoff layer 65 to peel off together with the liftoff layer 65. In this way, the inventive EUV exposure mask blank having the flank conductive film 64 is obtained (FIG. 6(e)). In this embodiment, the flank conductive film 64 material may be the same as, or different other than, that of the pattern-formation layer 12 and the conductive layer 13.

### Third Embodiment

The third embodiment is directed to a process of fabricating an EUV exposure mask blank having a flank conductive film by masking using a blocking plate, which process is well fit for where, upon formation of films on both major surfaces of the substrate, the sputtered films do not fully come down to the flank.

As depicted in FIG. 7(a), the pattern-formation layer 12 is provided on one major surface of the substrate 11 at a given thickness as by sputtering, and the electrically conductive layer 13 is formed on another major surface of the substrate 11 at a given thickness as by sputtering.

Then, as depicted in FIG. 7(b), the above substrate is placed in a mask holder 71 having a cutout space 72. Then, the flank of the substrate and the conductive layer 13 are covered up with a blocking plate 75 except the position to be provided with the desired conductive film.

Then, as depicted in FIG. 7(c), an electrically conductive material is sputtered or otherwise formed on the blocking plate 75 and the portion of the flank of the substrate 11 that is not covered up with the blocking plate to form an electrically conductive film 76 and a flank conductive film 74.

Then, the substrate 11 is removed out of the mask holder 71, thereby obtaining the inventive EUV exposure mask blank having the flank conductive film 74 (FIG. 7(d)). In this embodiment, the flank conductive film 74 material may be the same as, or different other than, that of the pattern-formation layer 12 and the conductive layer 13.

### Mask for EUV Exposure

FIG. 8 is schematically illustrative in section of the inventive mask 80 for EUV exposure that has been fabricated using the inventive EUV exposure mask blank depicted typically in FIG. 1.

The reference numerals given in FIG. 8 stand for the same sites as in FIG. 1, and the explanation of each layer in the EUV exposure mask is not given because it has been explained with reference to the mask blank.

The present invention is now explained in further details with reference to some examples.

### EXAMPLE

### Example 1

A 4.11 nm thick silicon film was formed on one major surface of an optically polished synthetic quartz substrate of 6 inches square (0.25 inch in thickness) by a DC magnetron sputtering technique using a silicon target in an argon atmosphere, subsequently followed by formation of a 2.74 nm thick molybdenum film using a molybdenum target, thereby forming one period of film. Forty such films were stacked one upon another. Finally, a silicon film was capped to form a reflective layer comprising a multilayer film of Mo and Si and adapted to reflect EUV light.

Then, a 50 nm thick SiO₂ film was formed on the above reflective layer by an RF magnetron sputtering technique using an SiO₂ target in an argon gas atmosphere, thereby obtaining an etching stopper layer.

Subsequently, a 0.1 μm thick TaN film was formed on the above SiO₂ film by a DC magnetron sputtering technique, thereby forming an absorptive layer capable of absorbing EUV light.

A substrate with the above reflective layer, etching stopper layer and absorptive layer provided as a pattern-formation layer on its one major surface was placed in a mask holder having a single cutout space.

Then, a 0.1 μm thick chromium film was formed on another major surface of the substrate facing away from the pattern-formation layer by an RF sputtering technique, thereby providing an electrically conductive layer. Simultaneously with the formation of the conductive chromium film, a 20 nm thick, 20 mm wide chromium film was formed as a flank conductive film on the portion of the flank of the substrate corresponding to the site provided with the cutout space, thereby obtaining a flank conductive film. In this way, there was an EUV exposure mask blank obtained, wherein the pattern-formation layer and the conductive layer were in conduction with each other via that chromium flank conductive film.

Then, an EB resist was coated on this EUV exposure mask blank to form a resist pattern by EB lithography. Then, a TaN layer was dry etched using Cl₂ gas, and the resist pattern was stripped off, after which the SiO₂ film was removed off with dilute fluoric acid to obtain an EUV exposure mask.

At each step of the above EUV exposure mask fabrication process, there was no peel of the flank Cr conductive film at all; attachment or detachment of the mask to or from the electrostatic chuck in the EUV aligner was readily done, so that high-accuracy transfer patterns could be obtained.

### Example 2

On one major surface of an optically polished SiO₂—TiO₂ substrate of 6 inches square, there was a pattern-formation layer formed, which was made up of a multilayer film layer consisting of 40 molybdenum films of 2.74 nm in thickness and 40 silicon films of 4.11 nm in thickness, a 0.01 μm chromium etching stopper layer and a 0.1 nm thick TaN absorptive layer, and on another major surface of the substrate there was a 0.1 μm thick CrN film formed.

Then, the above substrate was placed in a mask holder having two cutout spaces. While the site of the substrate with no flank conductive film formed was blocked off by a stainless blocking plate, a Ta film was formed by sputtering, thereby obtaining an EUV exposure mask blank which had two flank conductive films of 20 nm in thickness and 15 mm in width at the middles of the opposite substrate flanks and in which the pattern-formation layer and the conductive layer were in conduction with each other via the Ta flank conductive films.

Using the above EUV exposure mask blank, the absorptive layer and the etching stopper layer were pattern etched to obtain an EUV exposure mask. As in Example 1, the present EUV exposure mask was free of any peel of the flank conductive films at each fabrication process step; attachment or detachment of the mask to or from the electrostatic chuck in the EUV aligner was readily done, so that high-accuracy transfer patterns could be obtained.

What we claim is:

1. A mask blank for EUV exposure in which on one major surface of a substrate, a reflective layer adapted to reflect EUV light and an absorptive layer located on said reflective layer for absorption of said EUV light are at least provided as a pattern-formation layer, characterized in that an electrically conductive layer is formed on another major surface of said substrate, and said pattern-formation layer and said conductive layer on the opposite major surfaces of said substrate are in conduction with each other via one or more flank conductive films provided at a flank of said substrate.

2. The mask blank for EUV exposure according to claim 1, characterized in that said flank conductive film is made up of the same material as that of said conductive layer.

3. The mask blank for EUV exposure according to claim 1, characterized in that said flank conductive film is made up of the same material as that of said pattern-formation layer.

4. The mask blank for EUV exposure according to claim 1, characterized in that said flank conductive film is made up of a material contained in said conductive layer and said pattern-formation layer.

5. A mask for EUV exposure, characterized by being fabricated using the mask blank for EUV exposure according to any one of claims 1 to 4.

6. A fabrication process for a mask blank for EUV exposure in which on one major surface of a substrate, a reflective layer adapted to reflect EUV light and an absorptive layer located on said reflective layer for absorption of said EUV light are at least provided as a pattern-formation layer, characterized by involving steps of:
(1) forming said reflective layer on one major surface of said substrate,
(2) forming said absorptive layer on said reflective layer,
(3) forming an electrically conductive layer on another major surface of said substrate, and
(4) forming one or more flank conductive films at a flank portion of said substrate.

7. The EUV exposure mask blank fabrication process according to claim 6, characterized in that said conductive layer and said flank conductive film are simultaneously formed.

8. The EUV exposure mask blank fabrication process according to claim 6, characterized in that said pattern-formation layer and said flank conductive film are simultaneously formed.

9. The EUV exposure mask blank fabrication process according to claim 6, characterized in that said flank conductive film is formed by formation of said conductive layer and formation of said pattern-formation layer.

10. The EUV exposure mask blank fabrication process according to claim 6, characterized in that said flank conductive film is formed separately from formation of said conductive layer or formation of said pattern-formation layer.

11. The EUV exposure mask blank fabrication process according to any one of claims 6-10, characterized in that said flank conductive film is formed by a vacuum film-formation technique using a mask holder having a cutout space at a site with said flank conductive film formed thereon.
